(19) United States
(12) Patent Application Publication
(10) Pub. No.: US 2012/0048703 A1
(43) Pub. Date: Mar. 1, 2012

(54) Printed circuit board and method for avoiding electromagnetic interference

(76) Inventors: Michael Kotson, Longmont, CO (US); Eric Sidle, Firestone, CO (US); Gregory Harold Thamm, Broomfield, CO (US)

(21) Appl. No.: 12/923,098

(22) Filed: Sep. 1, 2010

(51) Int. Cl. H01H 13/76; H05K 1/11

(52) U.S. Cl. 200/5 A; 174/262

(57) ABSTRACT

A printed circuit board, especially for a computer keypad, and method for avoiding electromagnetic interference include conductive signal traces positioned on a surface of one of a nonconductive layer that is other than the outward facing surface of an outer nonconductive layer, and vertical interconnect accesses extending through the outer nonconductive layer and connecting the signal traces to the outward facing surface of the outer nonconductive layer, wherein each vertical interconnect access includes a conductive portion on the outward facing surface of the outer nonconductive layer, and the conductive portion has an area no greater than 1/10 the area of the asociated signal trace. Keys selectively connect pairs of vertical interconnect accesses.

### BACKGROUND OF THE INVENTION

The present invention relates to avoiding electromagnetic interference (EMI) involving a printed circuit board. It especially relates to avoiding electromagnetic interference involving a printed circuit board of a keyboard of a computer, particularly in military and aerospace applications.

For many military computing applications, a 200 volts-per-meter electromagnetic compatibility (EMC) testing is performed. The vast susceptibility issues arising from this kind of test are a direct result of outwardly-facing conductive signal traces on the external layers of printed circuit boards (PCBs). One example is the keyboard of a laptop computer. The outer-layer signal traces can easily act as antennas that absorb and re-transmit the 200-volts/meter burst of an electromagnetic (EM) susceptibility test. This leads to a wide-ranging number of issues causing failures in the electrical system. In current designs of standard keyboards, depressing any key “shorts” two conductive traces of a keyboard matrix of traces to complete a circuit and send a signal that the computer associates with the key that was depressed. The conductive signal traces act as electromagnetic-gathering antennas.

Current solutions for the above problem(s) involve shielding the boards, so that the external elecromagnetic radiation cannot get into the keyboard. However, not all PCBs can be well shielded. A keyboard is just one example of a printed circuit board that cannot be well shielded, where the rubber or plastic-coating on the keyboard is far too costly or is impractical, if a conductive material is added. Other (mechanical) failures will occur. In the end, not all PCBs can be coated.

### SUMMARY OF THE INVENTION

By the present invention, the amount of conductive material facing outward from an outer layer of a printed circuit board is reduced drastically by moving at least some, and preferably all, of the conductive signal traces from outwardly facing surfaces of outer layers of the printed circuit board to inwardly facing surfaces and/or inner layers. The conductive traces on the inwardly facing surfaces and/or inner layers of the printed circuit board are made accessible for interaction with, for example, the keys of a keyboard, by vertical interconnect accesses (vias) that connect the conductive traces to conductive points, or small areas, on the outer surface of the outer layer of the printed circuit board that are adjacent to the keys. With this arrangement, only points, or small areas, of conductive material are on the outer surface of the outer layer and, as a result, there is insufficient material on the outer surface of the outer layer to act as antennas that absorb and re-transmit the 200-volts/meter burst of an electromagnetic compatibility (EMC) test. Vias have a far smaller exposed area (by an order of 10 or more) of conductive material, such as copper, than traces have, but can still be shorted if more than one via is used.

Without exposed conductive traces acting as antennas in a high-voltage/meter EMC test, electromagnetic interference is drastically reduced, which is critical for many products in military and aerospace applications. Electromagnetic interference is the disruption of operation of an electronic device when the device is in the vicinity of an electromagnetic field (EM field) in the radio frequency (RF) spectrum that is caused by another electronic device. The present invention also extends the lifecycle of a product and improves its quality due to the fact that EMI susceptibility can cause damage over time.

### BRIEF DESCRIPTION OF THE DRAWING

FIG. 1 is a schematic illustration in plan of conductive traces on a portion of an outer surface of an outer layer of a printed circuit board according to the prior art;

FIG. 2 is a schematic illustration in plan of external ends of vias on a portion of an outer surface of an outer layer of a printed circuit board according to the present invention;

FIG. 3 is a schematic illustration in perspective of external ends of vias on a portion of a printed circuit board according to the present invention; and

FIG. 4 is a schematic illustration in cross section of vias on a portion of a printed circuit board according to the present invention used as a keypad, with a key in position.

### DETAILED DESCRIPTION OF THE PREFERRED EMBODIMENTS

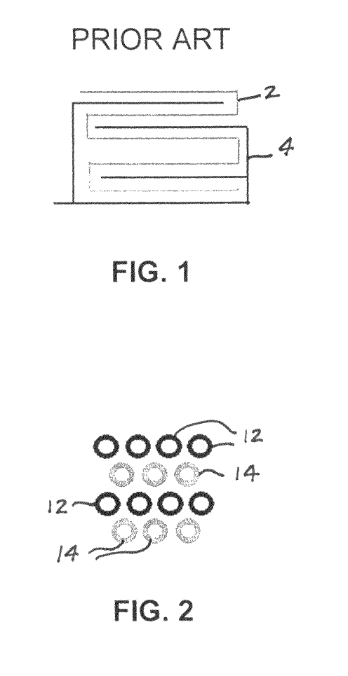

As can be seen from FIG. 1, known printed circuit boards have traces, such as a signal trace 2 and a ground trace 4, forming an outer conductive layer on an outward facing surface of an outer nonconductive layer. Such positioning of the signal traces presents electromagnetic interference issues. Typically, a matrix of such traces is provided.

As can be seen from FIG. 2, printed circuit boards according to the present invention, rather than having signal traces on an outward facing surface of an outer nonconductive layer, have the ends of vertical interconnect accesses (vias), such as a signal via 12 and a ground via 14, on an outward facing surface of an outer nonconductive layer.

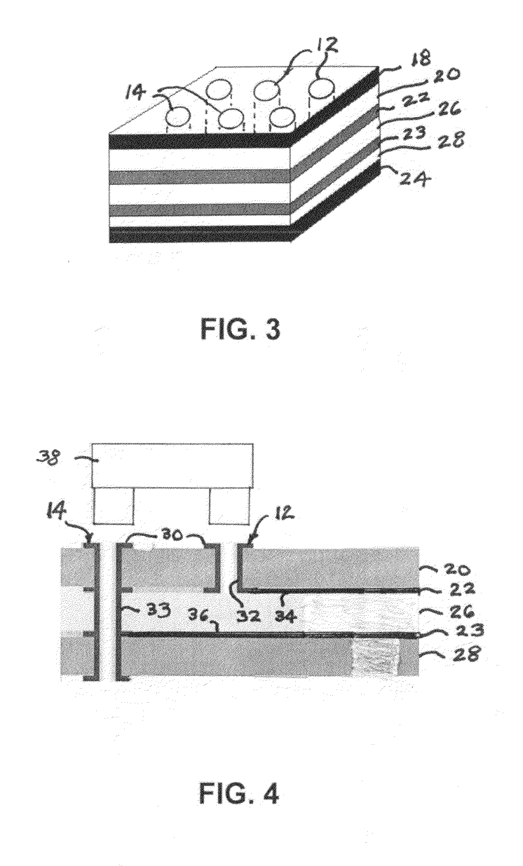

FIG. 3 shows a portion of a printed circuit board 16 having the ends of vias 12 and 14 comprising an outer conductive layer 18 positioned on an outward facing surface of an outer nonconductive layer 20. The printed circuit board 16 also includes inner conductive layers 22 and 23 and an outer conductive layer 24, as well as an inner nonconductive layer 26 and an outer nonconductive layer 28.

As can be appreciated from FIGS. 2 and 3 in connection with FIG. 4, which shows one of the ground vias 12 and one of the signal vias 14, outer ends of the vias are in the form of annular flanges 30. Other shapes can be used. The vias also include connecting portions 32 and 33, respectively, typically cylindrical, that extend through openings in the nonconductive layers and connect the outer ends of the vias to traces in inner conductive layers. In the illustrated embodiment, the ground via 12 is connected to a trace 34 in the inner conductive layer 22 on the inward facing side of the outer nonconductive layer 20, and the signal via 14 is connected to a trace 36 in the inner conductive layer 23. As is suggested by the connecting portion 33 of the signal via 14, the signal vias 14 can also be connected to traces in other conductive layers. The same is true of the ground vias 12, for which longer connecting portions can be provided. The outer end of each via 12 and 14 has an area no greater than 1/10 the area of the signal trace 34 or 36 to which the via connects. The traces and the vias can be made from copper.

Where the printed circuit board according to the present invention is used in a computer keypad, one 38 or more of a plurality of keys is selectively depressed to a position in which the key connects the outer end of a signal via 14 to the outer end of a ground via 12 to send to the computer a signal that the computer associates with the key that was depressed.

An array, or field, of the vias comprising rows of vias is provided. Every other row is a row of ground vias 12, and alternate rows are rows of signal vias 14. Outer conductive layers of the printed circuit board (not shown) are a shielding ground plane. The inner layers (which can number from 2 to n) contain the signals. Therefore, they are protected by the outer shielding ground layers. The alternate rows of vias have signals running from them to the inner layers, then to a system connector.

It will be apparent to those skilled in the art and it is contemplated that variations and/or changes in the embodiments illustrated and described herein may be made without departure from the present invention. Accordingly, it is intended that the foregoing description is illustrative only, not limiting, and that the true spirit and scope of the present invention will be determined by the appended claims.

1. A printed circuit board for avoiding electromagnetic interference comprising:
at least two nonconductive layers, including at least one outer nonconductive layer having an outward facing surface;
a conductive layer comprising a plurality of conductive traces positioned on a surface of one of the nonconductive layers that is other than the outward facing surface of the at least one outer nonconductive layer, at least some of the conductive traces being signal traces; and
a plurality of vertical interconnect accesses extending through the at least one outer nonconductive layer and connecting the traces to the outward facing surface of the at least one outer nonconductive layer, wherein each vertical interconnect access includes a conductive portion on the outward facing surface of the at least one outer nonconductive layer, said conductive portion of each vertical interconnect access that connects one of the signal traces to the outward facing surface of the at least one outer nonconductive layer has an area no greater than 1/10 the area of the signal trace that the conductive portion connects to the outward facing surface, and said conductive portion of each vertical interconnect access that connects one of the signal traces to the outward facing surface of the at least one outer nonconductive layer is adapted to be connected to the conductive portion of another one of the vertical interconnect accesses by a movable member to complete a circuit.

2. The printed circuit board of claim 1, wherein each vertical interconnect access comprises an opening through the outer nonconductive layer, a connecting portion of conductive material extending from one of the traces to the outward facing surface of the at least one outer nonconductive layer, and a flange of conductive material extending from the connecting portion onto the outward facing surface of the at least one outer nonconductive layer.

3. A computer keypad for avoiding electromagnetic interference comprising:
a printed circuit board having
at least two nonconductive layers, including at least one outer nonconductive layer having an outward facing surface;
a conductive layer comprising a plurality of conductive traces positioned on a surface of one of the nonconductive layers that is other than the outward facing surface of the at least one outer nonconductive layer, at least some of the conductive traces being signal traces;
a plurality of vertical interconnect accesses extending through the at least one outer nonconductive layer and connecting the traces to the outward facing surface of the at least one outer nonconductive layer; and
a plurality of keys,
wherein each vertical interconnect access includes a conductive portion on the outward facing surface of the at least one outer nonconductive layer, said conductive portion of each vertical interconnect access that connects one of the signal traces to the outward facing surface of the at least one outer nonconductive layer has an area no greater than 1/10 the area of the signal trace that the conductive portion connects to the outward facing surface, and one of said keys is movable to a position in which the key connects said conductive portion of each vertical interconnect access that connects one of the signal traces to the outward facing surface of the at least one outer nonconductive layer to the conductive portion of another one of the vertical interconnect accesses to send to a computer a signal that the computer associates with the key that was depressed.

4. The computer keypad of claim 3, wherein each vertical interconnect access comprise an opening through the outer nonconductive layer, a connecting portion of conductive material extending from one of the traces to the outward facing surface of the at least one outer nonconductive layer, and a flange of conductive material extending from the connecting portion onto the outward facing surface of the at least one outer nonconductive layer.

5. A method for avoiding electromagnetic interference in a printed circuit board comprising:
providing at least two nonconductive layers, including at least one outer nonconductive layer having an outward facing surface;
positioning a conductive layer comprising a plurality of conductive traces on a surface of one of the nonconducting layers that is other than the outward facing surface of the at least one outer nonconductive layer, wherein at least some of the conductive traces are signal traces; and
extending a plurality of vertical interconnect accesses through the at least one outer nonconductive layer to connect the traces to the outward facing surface of the at least one outer nonconductive layer, wherein each vertical interconnect access includes a conductive portion on the outward facing surface of the at least one outer nonconductive layer, said conductive portion of each vertical interconnect access that connects one of the signal traces to the outward facing surface of the at least one outer nonconductive layer has an area no greater than 1/10 the area of the signal trace that the conductive portion connects to the outward facing surface, and said conductive portion of each vertical interconnect access that connects one of the signal traces to the outward facing surface of the at least one outer nonconductive layer is adapted to be connected to the conductive portion of another one of the vertical interconnect accesses by a movable member to complete a circuit.

6. The method of claim 5, wherein each vertical interconnect access comprises an opening through the outer nonconductive layer, and the act of extending comprises extending a connecting portion of conductive material from one of the traces to the outward facing surface of the at least one outer nonconductive layer, and extending a flange of conductive material from the connecting portion onto the outward facing surface of the at least one outer nonconductive layer.
